(19) United States
(12) Patent Application Publication
(10) Pub. No.: US 2009/0073654 A1
(43) Pub. Date: Mar. 19, 2009

(54) Compact surface-mount heat exchanger

(76) Inventors: James M. Beam, Montgomery, AL (US); Bernard A. Kuster, Longmont, CO (US); Jeffrey Allen Wilson, Wetumpka, AL (US)

Correspondence Address: MEREK, BLACKMON & VOORHEES, LLC, 673 S. WASHINGTON ST, ALEXANDRIA, VA, 22314, US

(21) Appl. No.: 11/898,668

(22) Filed: Sep. 14, 2007

(51) Int. Cl. H05K 7/20

(52) U.S. Cl. 361/696; 165/104.34

(57) ABSTRACT

A temperature-stable portable device includes equipment enclosed in a portable case that seals the equipment from its surroundings, and a heat exchanger distinct from the case and attached to the exterior of the case by removable fasteners. The heat exchanger extends across at least most of a major surface of the case and is positioned to receive heat from the major surface by conduction. A sheet of material having good thermal conductivity is interposed between, and in contact with, the heat exchanger and the major surface of the case. The heat exchanger defines a chamber that is open to the atmosphere and has parallel flow passages and an arrangement for moving a heat exchange fluid through the chamber and out to the atmosphere in order to remove heat from the heat exchanger by convection.

### FIELD OF THE INVENTION

The present invention relates to the cooling of portable equipment, especially heat-generating portable equipment, for example, laptop computers.

### BACKGROUND OF THE INVENTION

Portable equipment, especially portable electronic equipment, such as laptop computers, needs to be cooled without compromising the equipment by additional exposure to, for example, forced air, moisture, dirt, sand and/or dust from outside the equipment. Most laptops allow air to flow through the casing in order to provide cooling. However, in laptops and other equipment designed for rugged conditions, for example, battlefield conditions, the equipment casing is sealed to keep out dirt, moisture, and the like. Heat generated by equipment having sealed cases is dissipated first in the cases and then by natural convection from the cases to the atmosphere. When the heat generation of the equipment exceeds the capacity of the case and the surrounding air to transfer the heat by natural convection, the temperature of the equipment increases to levels that decrease the performance and utility of the equipment. Known solutions to this problem of equipment having sealed cases include relatively large, heavy, noisy and expensive heat sinks, heat pipes, fans and combinations thereof. In some known solutions, at least part of a cooling structure extends into the equipment case to one or more internal components.

### SUMMARY OF THE INVENTION

By the present invention, portable equipment is cooled by employing a slim, compact heat exchanger to dissipate heat from a case of the portable equipment, thereby reducing the external temperatures of the case while protecting the equipment from exposure to forced air, moisture, and/or dirt, sand and/or dust.

According to the present invention, the heat exchanger is distinct from and attached to the equipment, so that the heat exchanger receives heat, at least primarily by conduction, from the equipment case and then dissipates the heat from the heat exchanger through the use of cooling fluid passages and mechanisms for forcing cooling fluid through the passages. The heat exchanger is attached to an exterior major surface of the case of the portable equipment, for example, the bottom of a laptop computer, the heat exchanger conforming to and covering substantially the entire surface area of the major surface. As a result, the internal components of the equipment can remain sealed in the case of the equipment, isolated from the environment, while greater amounts of heat are removed from the equipment than in the prior art. The isolation also maintains the reliability of the equipment, while allowing the equipment to dissipate heat and maintain stable system temperatures.

The material of the heat exchanger is light in weight and has good thermal conductivity. For example, the heat exchanger can have a base and a chassis made of a magnesium alloy and a cover made of an aluminum alloy. The heat exchanger includes a plurality of parallel flow passages that extend across most of the area of the top and bottom surfaces of the heat exchanger and across most of the adjacent major surface of the equipment case, so that heat is dissipated from all of the area of the top surface of the heat exchanger. The heat exchanger also includes fans for forcing air through the passages.

The separate heat exchanger according to the present invention dissipates the heat generated by the portable equipment by receiving the heat by conduction directly from the equipment and then transferring the received heat into airflow by forced convection using one or more compact fans. The combination of direct conduction and forced convection heat flows significantly dissipates heat while being low in profile, relatively quiet, and very reliable.

The heat exchanger according to the present invention has a defined airflow in that it has flow passages each having an inlet and an outlet. There are a large plurality of flow passages that comprise two main flow paths, each flow path conducting air in a ‘U’ terminating in a 90 degree turn to the side at the top of the downstream leg of the ‘U’. The flow passages cover substantially the entire area of the portable equipment where heat is being generated. Fans that provide forced airflow through the flow passages are positioned in the heat exchanger adjacent to a heat exchanger inlet structure having an air filter in order to filter out dust.

A material having good heat conducting properties is interposed between the heat exchanger and the major surface of the case of the portable equipment to increase the area of contact, and/or improve contact, between the heat exchanger and the major surface of the case and thereby enhance conduction. In an illustrated embodiment, the material having good heat conducting properties is in the form of a sheet of thermal interface material that covers substantially the entire area of the major surface of the case of the portable equipment.

The heat exchanger has only a few main components and uses standard hardware, such as screws, lock washers and washers, that is generally available in hardware stores, rather than specialized hardware, because the latter can be difficult to obtain and replace. Elastomeric bumpers to protect the temperature-stable portable device from violent shaking and jarring are provided on the bottom of the heat exchanger instead of on the bottom of the portable equipment, such as a laptop.

### BRIEF DESCRIPTION OF THE DRAWINGS

FIG. 1 is a perspective view, taken from the top, front and right side, of a temperature-stable portable device comprising a heat exchanger of the present invention mounted on a laptop computer;

FIG. 2 is an exploded perspective view of the heat exchanger of FIG. 1 separated from the laptop computer, with a thermal interface sheet interposed;

FIG. 3 is a perspective view, taken from the bottom, front and left side, of the heat exchanger of FIG. 1;

FIG. 4 is an exploded perspective view of the heat exchanger of FIG. 3, with a bottom panel spaced from a body of the heat exchanger;

FIG. 5 is a bottom plan view of the body of the heat exchanger of FIG. 4; and

FIG. 6 is a perspective view, taken from the top, rear and right side, of the heat exchanger of FIG. 1, with a filter and filter-carrying structure spaced from the remainder of the heat exchanger.

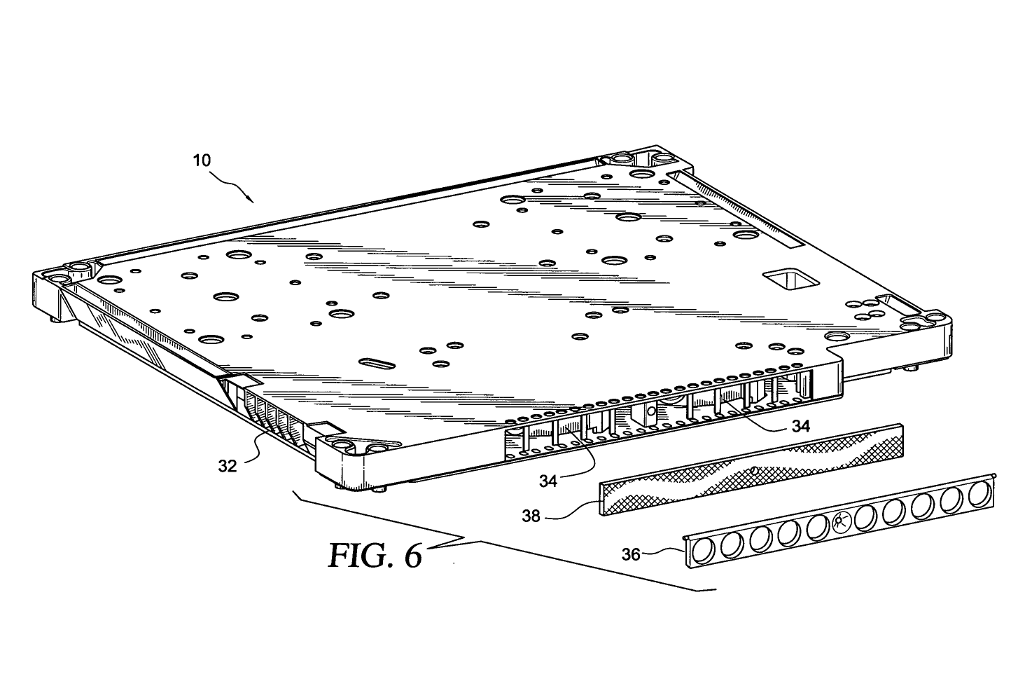

### DETAILED DESCRIPTION OF THE PREFERRED EMBODIMENTS

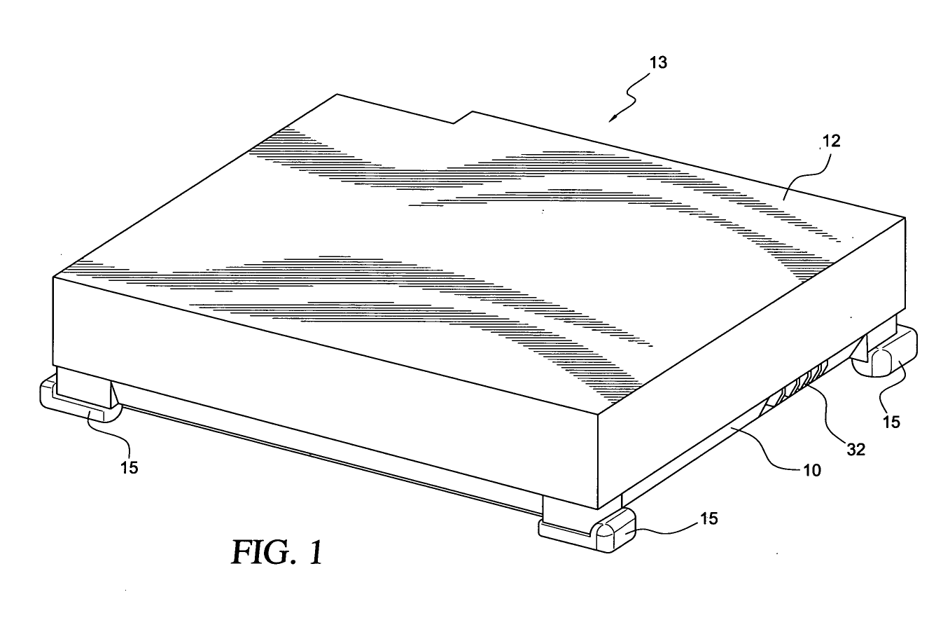

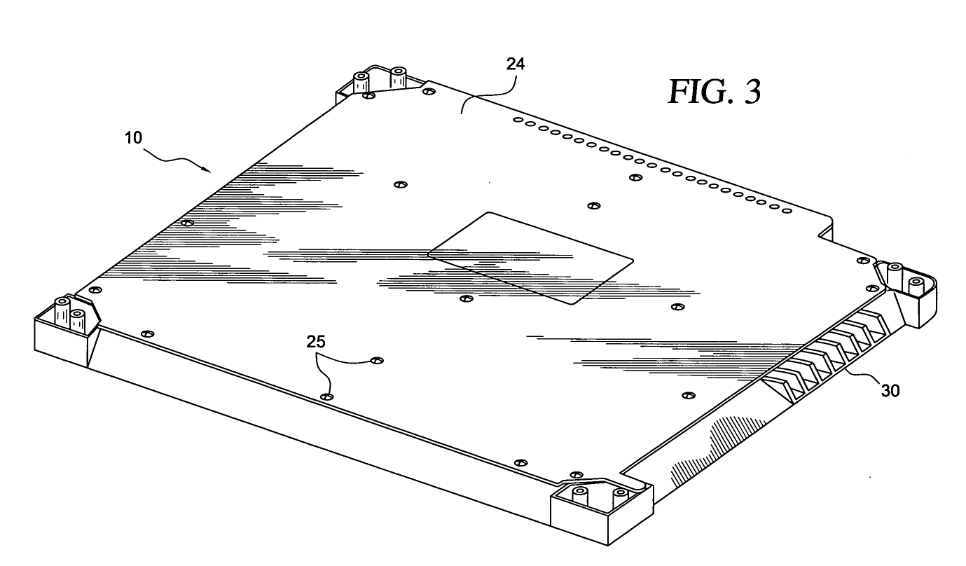

As can be seen from FIGS. 1-3, the heat exchanger according to the present invention, which is designated generally by the reference numeral 10, is distinct from and attached to portable equipment 12, particularly heat-generating equipment, such as a laptop computer, to dissipate heat therefrom and thereby provide a temperature-stable portable device 13. In FIG. 1 the heat exchanger 10 is attached to the underside of the case, the case being the visible part of the portable equipment 12 in the drawing figures. The case seals the portable equipment 12 from its surroundings, thereby protecting the portable equipment from dirt and moisture. The top wall of the heat exchanger 10 is shaped to conform to the major surface of the case of the portable equipment 12 and is placed in contact with the major surface of the case of the portable equipment in order to efficiently transfer heat away from the case by conduction. In the illustrated embodiment, the top wall of the heat exchanger 10 conforms by being planar, since the major surface of the case of the portable equipment 12, in this embodiment, the bottom, is planar. It can be appreciated that the heat exchanger 10 is slim and compact, and relatively simple in construction, being made of only a few components. The heat exchanger 10 dissipates heat from the case of the portable equipment 12, thereby reducing the external temperatures of the case while enabling the portable equipment to be isolated from forced air, moisture, dirt, sand and dust.

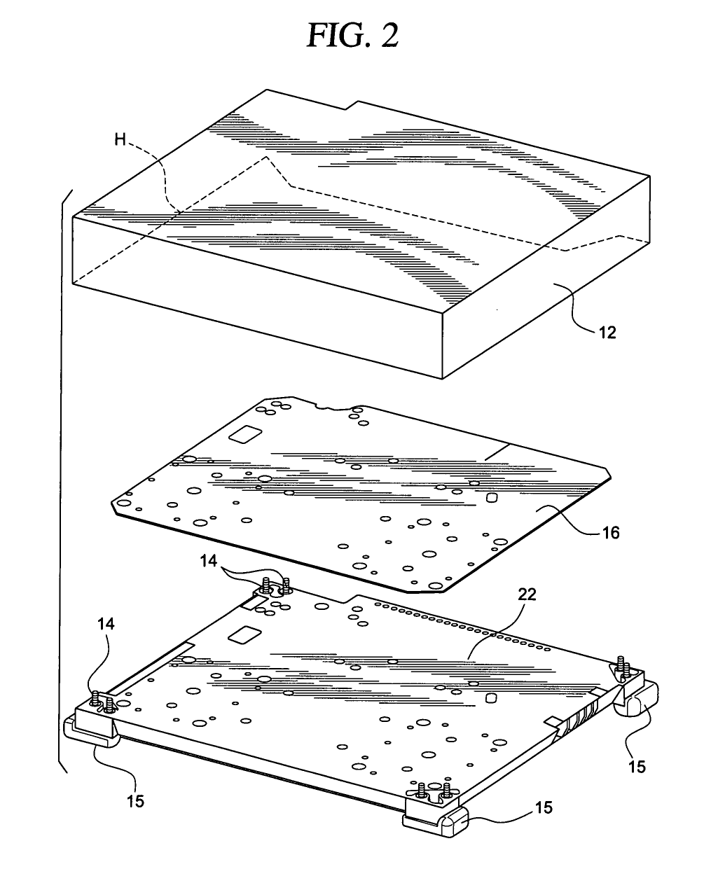

According to the present invention, the heat exchanger 10 receives heat, at least primarily by conduction, from the case of the portable equipment 12 and then dissipates the heat to the surroundings. As is shown in FIGS. 1 and 2, the heat exchanger 10 is removably attached to an exterior major surface of the case, which can be, for example, the bottom of a laptop computer, by standard hardware 14, such as screws, lock washers and washers. Elastomeric bumpers 15 are provided on bottom corners of the heat exchanger 10 instead of on the bottom of the portable equipment 12 to protect the temperature-stable portable device 13 from violent shaking and jarring. The heat exchanger 10 covers substantially the entire area of the major surface of the case of portable equipment 12, thus defining a coextensive area in which the heat exchanger is coextensive with the major surface of the exterior of the case. As a result of the nature of the heat exchanger 10, that is, distinct from the portable equipment 12, isolation is provided for the internal components of the portable equipment 12, while heat is removed from the equipment. The isolation maintains the case as a sealed enclosure and also maintains the reliability of the portable equipment 12, while allowing the equipment to dissipate heat and maintain stable system temperatures.

As can be seen in FIG. 2, a material 16 having good heat conducting properties is interposed between, and in contact with, the heat exchanger 10 and the major surface of the case of the portable equipment 12 to increase the area of contact between the heat exchanger and the case and thereby enhance heat conduction. In the illustrated embodiment, the heat conducting material 16 having good heat conducting properties is in the form of a sheet of thermal interface material that covers substantially the entire area of the major surface and substantially all of the coextensive area. The sheet of thermal interface material can comprise aluminum foil having a layer of dry thermal grease on each side. A layer of, for example, 0.2 mil of such a dry thermal grease on each side of the aluminum foil is suitable. One suitable thermal interface material is commercially available as a sheet of aluminum with dry thermal grease already in place on both sides of the aluminum sheet. It is available under the trademark MICRO-FAZE from AOS Thermal Compounds of Eatontown, N.J. The thermal conductivity of the aluminum is believed to be about 168 W/mK, and the thermal conductivity of the combined aluminum sheet and thermal grease on both sides is 2.8 W/mK.

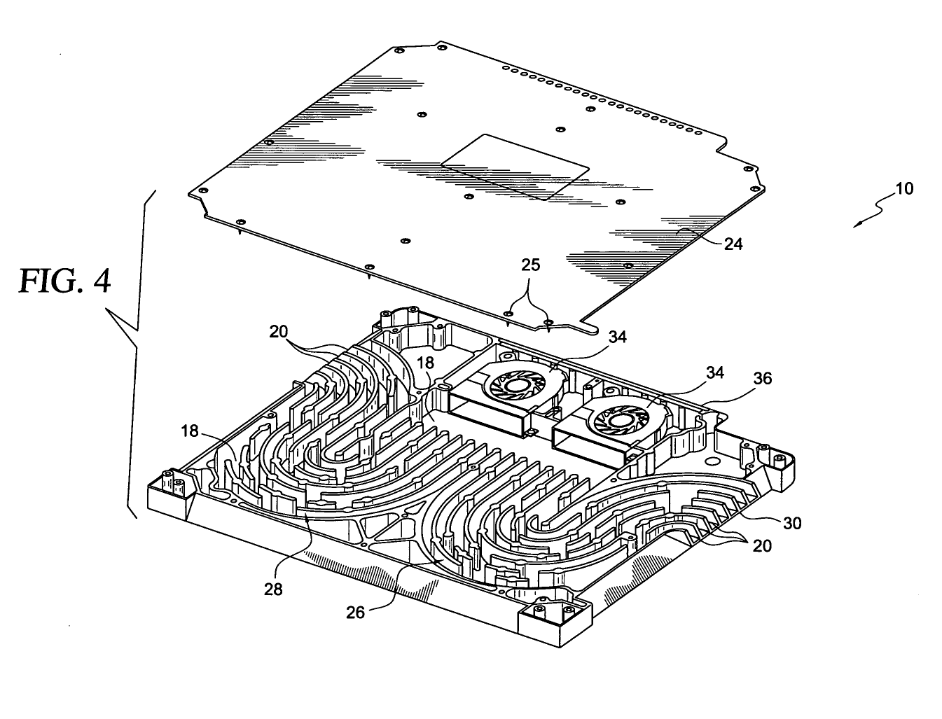

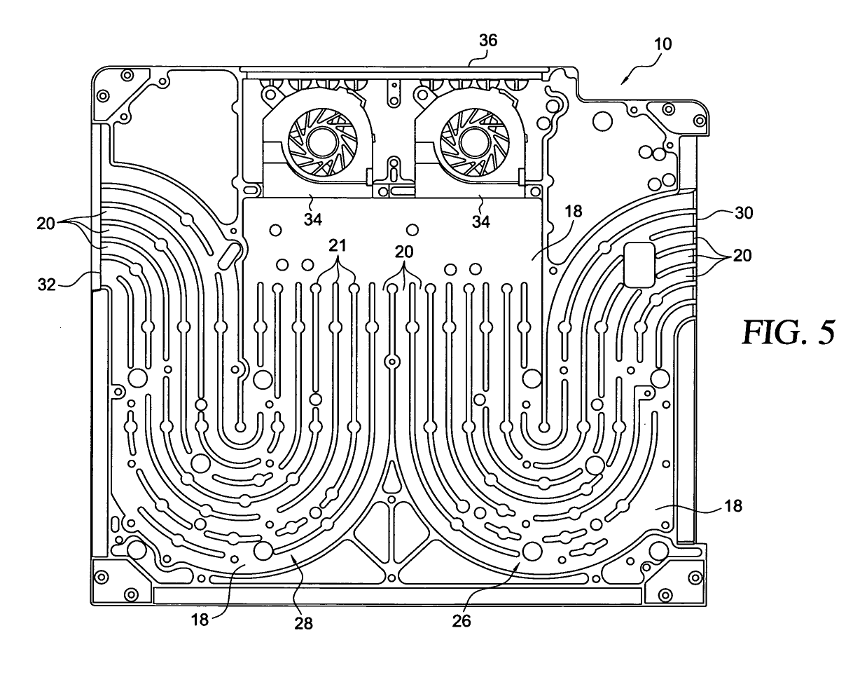

As can be seen in FIGS. 4 and 5, the heat exchanger 10 defines a chamber 18 that is open to the atmosphere, the chamber occupying at least most of the volume of the heat exchanger. The heat exchanger 10 has a defined airflow in that it includes a plurality of parallel flow passages 20 that extend across most of the area of top and bottom walls 22 and 24, respectively, of the heat exchanger, across most of the adjacent major surface of the case of the portable equipment 12, and out to the atmosphere, so that heat is dissipated from all of the area of the top surface of the heat exchanger. The flow passages 20 comprise two main flow paths 26 and 28, respectively, each comprising a ‘U’ and a 90 degree turn at the top of the downstream leg of the ‘U’ to an outlet 30 and 32, respectively, in a wall of the heat exchanger 10. The flow passages 20 are defined by parallel partitions 21 that extend perpendicularly from the top wall 22 to the bottom wall 24. The bottom wall 24 can be defined by a plate attached by screws 25 to the remainder of the heat exchanger 10.

Heat-generating equipment, such as a laptop computer, has heat-generating areas, such as the heat generating area H indicated by broken lines in FIG. 2. When the heat exchanger 10 of the present invention is used with heat-generating portable equipment 12, a portion of a major surface of the exterior of the case of the portable equipment is adjacent to the heat generating areas, and the flow passages 20 of the heat exchanger extend across substantially all of that portion. The heat exchanger 10 also includes a mechanism, for example, one or more compact fans 34 for forcing a heat exchange fluid, such as air, through the flow passages 20. In the illustrated embodiment, the fans 34 are positioned near one side of the heat exchanger 10, adjacent to an air inlet structure 36 carrying a removable air filter 38.

The separate heat exchanger 10 according to the present invention dissipates the heat generated by the portable equipment 12 by receiving the heat by conduction directly from the portable equipment and transferring the received heat into airflow by forced convection using, in the illustrated embodiment, the fans 34. The combination of direct conduction and forced convection heat flows significantly dissipates heat energy while being low in profile, relatively quiet, and very reliable.

It will further be appreciated by those skilled in the art and it is contemplated that variations to the embodiments illustrated and described herein may be made without departing from the spirit and scope of the present invention. Accordingly, it is intended that the foregoing description is illustrative only, and the true spirit and scope of the invention will be determined by the appended claims.

1. A temperature-stable portable device comprising:
equipment enclosed in a portable case that seals the equipment from its surroundings, said case having an exterior having a major surface; and
a heat exchanger distinct from said case and attached to the exterior of said case, said heat exchanger extending across at least most of said major surface of said case and being positioned to receive heat by conduction from said major surface.

2. The temperature-stable portable device of claim 1, wherein said heat exchanger extends across substantially all of said major surface of the exterior of said case.

3. The temperature-stable portable device of claim 1, further comprising a thermally conductive sheet of material interposed between, and in contact with, the heat exchanger and said major surface of the exterior of said case.

4. The temperature-stable portable device of claim 3, wherein the thermally conductive sheet of material comprises aluminum foil.

5. The temperature-stable portable device of claim 4, wherein the thermally conductive sheet of material further comprises a layer of thermally conductive grease on each side of the aluminum foil.

6. The temperature-stable portable device of claim 3, wherein said heat exchanger defines a coextensive area in which the heat exchanger is coextensive with said major surface of the exterior of said case, and said thermally conductive sheet of material extends across substantially all of said coextensive area.

7. The temperature-stable portable device of claim 1, wherein said heat exchanger defines a chamber that is open to the atmosphere, said chamber occupying at least most of the volume of the heat exchanger.

8. The temperature-stable portable device of claim 7, wherein said heat exchanger includes means for moving a heat exchange fluid through the chamber and out to the atmosphere in order to remove heat from the heat exchanger by convection.

9. The temperature-stable portable device of claim 7, wherein said heat exchanger further includes parallel flow passages in said chamber, and means for moving a heat exchange fluid through the parallel flow passages and out to the atmosphere.

10. The temperature-stable portable device of claim 9, wherein said equipment has heat generating areas, a portion of said major surface of said exterior of said case is adjacent to heat generating areas of said equipment, and said parallel flow passages extend across substantially all of said portion of said major surface.

11. The temperature-stable portable device of claim 1, wherein said heat exchanger is attached to said case by removable fasteners.

12. The temperature-stable portable device of claim 1, wherein said heat exchanger defines a bottom surface and corners defined in part by said bottom, and said heat exchanger further comprises elastomeric bumpers mounted on said heat exchanger at said corners.

13. A heat exchanger for equipment enclosed in a portable case that has an exterior having a major surface, comprising
a surface shaped to conform to the major surface of the portable case, wherein said heat exchanger is adapted to be attached to the exterior of the case such that 1) said surface of said heat exchanger extends across at least most of the major surface of the case to define a coextensive area in which said surface of said heat exchanger and the major surface of the case are coextensive with one another, and 2) said surface of said heat exchanger receives heat from the major surface of the case by conduction.

14. The heat exchanger of claim 13, further comprising a thermally conductive sheet of material in contact with said surface of the heat exchanger.

15. The heat exchanger of claim 14, wherein said sheet of material extends across at least most of said surface of the heat exchanger.

15. The heat exchanger of claim 14, wherein the thermally conductive sheet of material comprises aluminum foil.

16. The heat exchanger of claim 15, wherein the thermally conductive sheet of material further comprises a layer of thermally conductive grease on each side of the aluminum foil.

17. The heat exchanger of claim 13, further comprising a chamber that is open to the atmosphere.

18. The heat exchanger of claim 17, wherein said heat exchanger includes means for moving a heat exchange fluid through the chamber and out to the atmosphere in order to remove heat from the heat exchanger by convection.

19. The heat exchanger of claim 17, wherein said heat exchanger further includes parallel flow passages in said chamber, and means for moving a heat exchange fluid through the parallel flow passages and out to the atmosphere.

20. The heat exchanger of claim 19, wherein said parallel flow passages extend across most of said surface of said heat exchanger.

21. The heat exchanger of claim 13, further comprising removable fasteners adapted to attach said heat exchanger to a portable case.

22. The heat exchanger of claim 13, wherein said heat exchanger defines a bottom surface and corners defined in part by said bottom, and said heat exchanger further comprises elastomeric bumpers mounted on said heat exchanger at said corners.

23. A method for cooling portable equipment while protecting the equipment from dirt and moisture comprising:
enclosing the equipment in a portable case that seals the equipment from its surroundings; and
attaching to the exterior of the case a heat exchanger that is distinct from the case such that the heat exchanger extends across at least most of a major surface of the case and is positioned to receive heat by conduction from said major surface.

24. The method of claim 23, further comprising interposing a thermally conductive sheet of material between, and in contact with, the heat exchanger and said major surface of the case.

25. The method of claim 24, wherein the sheet of material is extended across substantially all of a coextensive area in which the heat exchanger is coextensive with said major surface of the case.

26. The method of claim 23, further comprising moving a heat exchange fluid through a chamber occupying at least most of the volume of the heat exchanger and out to the atmosphere in order to remove heat from the heat exchanger by convection.

27. The method of claim 26, wherein the heat exchange fluid is moved through the chamber and out to the atmosphere through parallel flow passages.

28. The method of claim 26, wherein the heat exchange fluid is moved through the chamber and out to the atmosphere through parallel flow passages extending across most of a coextensive area in which the heat exchanger is coextensive with said major surface of the case.
